(19) United States
(12) Patent Application Publication
(10) Pub. No.: US 2025/0272655 A1
(43) Pub. Date: Aug. 28, 2025

(54) MACHINE LEARNING TECHNIQUES FOR BUILDING CONSTRUCTION

(71) Applicant: Blueprint Pro AI LLC, Orlando, FL (US)

(72) Inventors: Bradley MARTINDALE, Canton, GA (US); Filipe MENDES, Ocoee, FL (US); Barry OSTRANDER, Woodstock, GA (US)

(21) Appl. No.: 19/063,761

(22) Filed: Feb. 26, 2025

Related U.S. Application Data
(60) Provisional application No. 63/557,637, filed on Feb. 26, 2024.

(51) Int. Cl. G06Q 10/0875; G06Q 50/08

(52) U.S. Cl. CPC G06Q 10/0875; G06Q 50/08

(57) ABSTRACT

Machine learning techniques for construction. In an example, a computing system accesses a construction document associated with a construction project. The construction document includes pages. The computing system provides the pages to a first machine learning model to generate classified pages. Each classified page identifies a page type and a region. The computing system provides the classified pages to a second machine learning model to generate segmented pages comprising one or more objects. Each object corresponds to a building element. The computing system may analyze the one or more objects to determine coordinates and properties. The computing system may determine, from the coordinates and the properties, a bill of materials associated with the construction project.

### CROSS-REFERENCE TO RELATED APPLICATIONS

The present application claims the benefit of U.S. Provisional Patent Application No. 63/557,637, filed Feb. 26, 2024, the contents of which is hereby incorporated for all purposes.

### FIELD

The present disclosure relates to machine learning. In particular, and without limitation, disclosed techniques relate to using machine learning techniques to analyze construction documents.

### BACKGROUND

Construction projects typically rely on one or more construction documents (e.g., blueprints). These documents illustrate internal and external structures of building to be built, the required materials, and so forth. But traditional approaches to deriving a comprehensive and detailed list of all materials, components, parts, and assemblies required for a specific construction project (e.g., a bill of materials) may be inaccurate.

### SUMMARY

In some aspects, the techniques described herein relate to a method including: accessing a construction document associated with a construction project, the construction document including pages; providing the pages to a first machine learning model to generate classified pages, wherein each classified page identifies a page type and a region; providing the classified pages to a second machine learning model to generate segmented pages including one or more objects, each object corresponding to a building element; analyzing the one or more objects to determine coordinates and properties; and determining, from the coordinates and the properties, a bill of materials associated with the construction project.

In some aspects, the techniques described herein relate to an apparatus including: A memory; and a processor coupled to the memory and configured to perform operations including: accessing a construction document associated with a construction project, the construction document including pages; providing the pages to a first machine learning model to generate classified pages, wherein each classified page identifies a page type and a region; providing the classified pages to a second machine learning model to generate segmented pages including one or more objects, each object corresponding to a building clement; analyzing the one or more objects to determine coordinates and properties; and determining, from the coordinates and the properties, a bill of materials associated with the construction project.

In some aspects, the techniques described herein relate to a non-transitory computer readable medium including instructions, that when executed by a processor, cause the processor to perform operations including: accessing a construction document associated with a construction project, the construction document including pages; providing the pages to a first machine learning model to generate classified pages, wherein each classified page identifies a page type and a region; providing the classified pages to a second machine learning model to generate segmented pages including one or more objects, each object corresponding to a building clement; analyzing the one or more objects to determine coordinates and properties; and determining, from the coordinates and the properties, a bill of materials associated with the construction project.

Various embodiments of the disclosure are discussed in detail below. While specific implementations are discussed, this is done for illustration purposes only. A person skilled in the relevant art will recognize that other components and configurations can be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described to avoid obscuring the description. References to one or an embodiment in the present disclosure can be references to the same embodiment or any embodiment; and such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which can be exhibited by some embodiments and not by others.

The terms used in this specification generally have their ordinary meanings in the art, within the context of the disclosure, and in the specific context where each term is used. Alternative language and synonyms can be used for any one or more of the terms discussed herein, and no special significance should be placed upon whether a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles can be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

### BRIEF DESCRIPTION OF THE DRAWINGS

FIG. 1 depicts a system for using machine learning for construction document analysis, in accordance with an aspect of the present disclosure.

FIGS. 2A-2C depict examples of a construction document, in accordance with an aspect of the present disclosure.

FIG. 3 depicts an example of a bill of materials, in accordance with an aspect of the present disclosure.

FIG. 4 depicts a client-server system for using machine learning for construction document analysis, in accordance with an aspect of the present disclosure.

FIG. 5 depicts an example of a process for using machine learning to analyze a construction document, in accordance with an aspect of the present disclosure.

FIG. 6 depicts an example of a process for using machine learning to classify pages of a construction document, in accordance with an aspect of the present disclosure.

FIG. 7 depicts an example of a process for using machine learning to roof data from pages of a construction document, in accordance with an aspect of the present disclosure.

FIG. 8 depicts an example of a page depicting roofing information, in accordance with an aspect of the present disclosure.

FIG. 9 depicts an example of a mask illustrating a roof illustration of a construction document, in accordance with an aspect of the present disclosure.

FIG. 10 depicts an example of an output illustrating a roof within a construction document, in accordance with an aspect of the present disclosure.

FIG. 11 depicts an example of a process for using machine learning to identify information about walls from pages of a construction document, in accordance with an aspect of the present disclosure.

FIG. 12 depicts an example of a structural document, in accordance with an aspect of the present disclosure.

FIG. 13 depicts an example of a mask identifying interior walls, in accordance with an aspect of the present disclosure.

FIG. 14 depicts an example of a mask identifying exterior walls, in accordance with an aspect of the present disclosure.

FIG. 15 depicts an example of a final wall visualization derived from classifications of a machine learning model, in accordance with an aspect of the present disclosure.

FIG. 16 depicts an example of a process for training a machine learning model, in accordance with an aspect of the present disclosure.

FIG. 17 is a diagram illustrating an example of a computer system, in accordance with an aspect of the present disclosure.

In the appended figures, similar components and/or features can have the same reference label. Further, various components of the same type can be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

In the following description, for the purposes of explanation, specific details are set forth to provide a thorough understanding of certain inventive embodiments. However, it will be apparent that various embodiments may be practiced without these specific details. The figures and description are not intended to be restrictive. The word “exemplary” is used herein to mean “serving as an example, instance, or illustration.” Any embodiment or design described herein as “exemplary” is not necessarily to be construed as preferred or advantageous over other embodiments or designs.

Aspects of the present disclosure relate to machine learning techniques for construction projects, including analyzing construction documents. Certain aspects provide improvements relative to existing solutions such as generating more accurate estimates of building materials and costs for a construction project. Further, certain aspects improve computing performance and/or reduce memory consumption relative to existing algorithmic-based solutions.

The following non-limiting example is introduced for discussion purposes. In the example, a computer system analyzes a construction document having multiple pages, each of which illustrates a different facet of a construction project. The computer system applies a machine learning model, such as a classification model, to the pages. The model identifies a respective page type for each page. For instance, the model may identify that a first page illustrates a roof, a second page illustrates walls, a third page relates to building schedules, a fourth page to electrical systems, and so forth.

Continuing the example, the computer system uses one or more additional machine learning models, each of which is trained to analyze a particular type of page. These specialized models each derive details for their respective inputs, including identifying objects such as specific building elements. For instance, the system can identify interior walls, exterior walls, cased openings, roof elements, and so forth. From these identified objects, the system calculates a bill of materials including details about materials required and other relevant information which may be used for the project.

As discussed, certain aspects use machine learning. As used herein, a “machine learning model” generally encompasses instructions, data, and/or a model configured to receive input, and apply one or more of a weight, bias, classification, or analysis on the input to generate an output. The output may include, for example, a classification of the input, an analysis based on the input, a design, process, prediction, or recommendation associated with the input, or any other suitable type of output. A machine learning model is generally trained using training data, e.g., experiential data and/or samples of input data, which are fed into the model to establish, tune, or modify one or more aspects of the model, e.g., the weights, biases, criteria for forming classifications or clusters, or the like. Aspects of a machine learning model may operate on an input linearly, in parallel, via a network (e.g., a neural network), or via any suitable configuration.

The execution of the machine learning model may include deployment of one or more machine learning techniques, such as linear regression, logistic regression, random forest, gradient boosted machine, deep learning, and/or a deep neural network. Supervised and/or unsupervised training may be employed. For example, supervised learning may include providing training data and labels corresponding to the training data, e.g., as ground truth. Unsupervised approaches may include clustering, classification or the like. K-means clustering or K-Nearest Neighbors may also be used, which may be supervised or unsupervised. Combinations of K-Nearest Neighbors and an unsupervised cluster technique may also be used. Any suitable type of training may be used, e.g., stochastic, gradient boosted, random seeded, recursive, epoch or batch-based, etc.

While several of the examples herein involve certain types of machine learning, techniques according to this disclosure may be adapted to any suitable type of machine learning. Further, the examples above are illustrative only. The techniques and technologies of this disclosure may be adapted to any suitable activity.

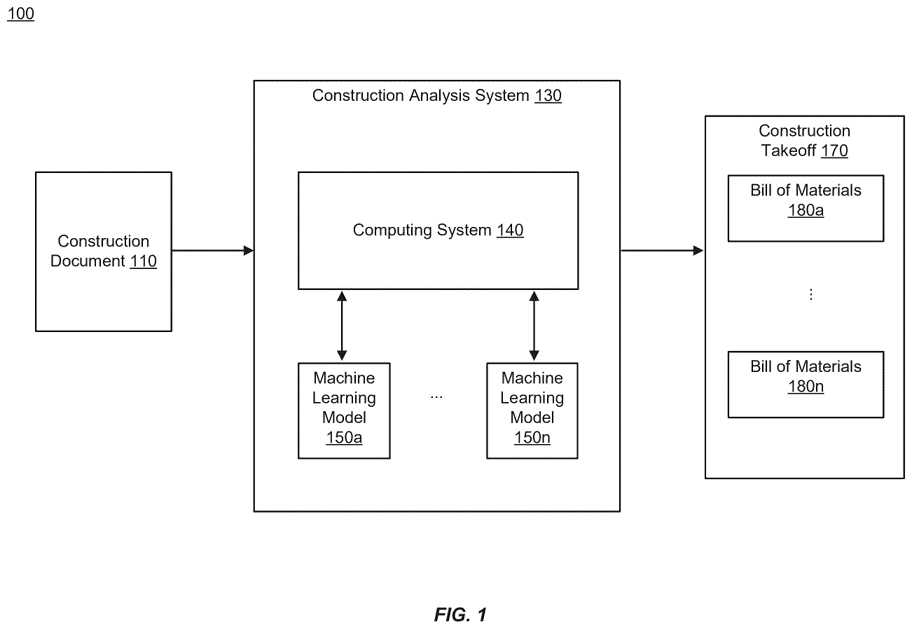

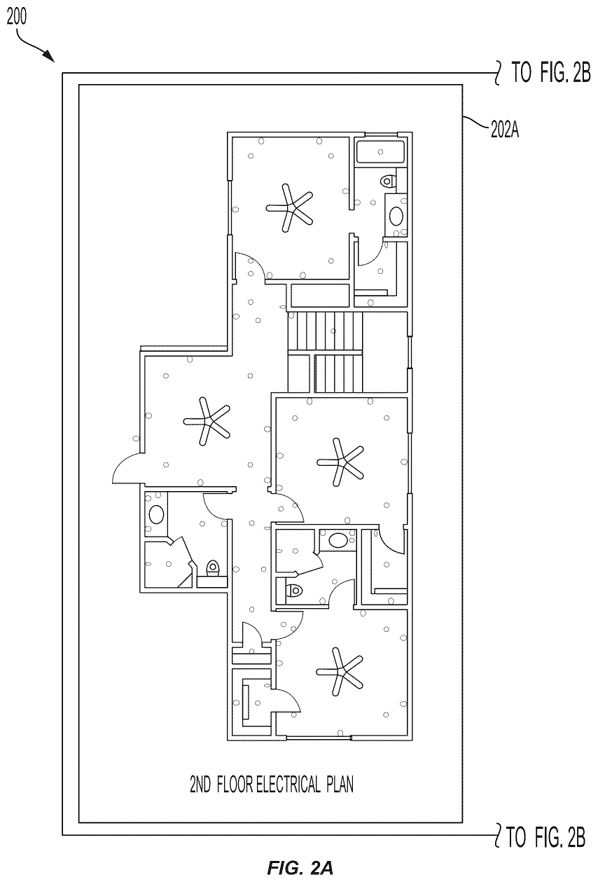

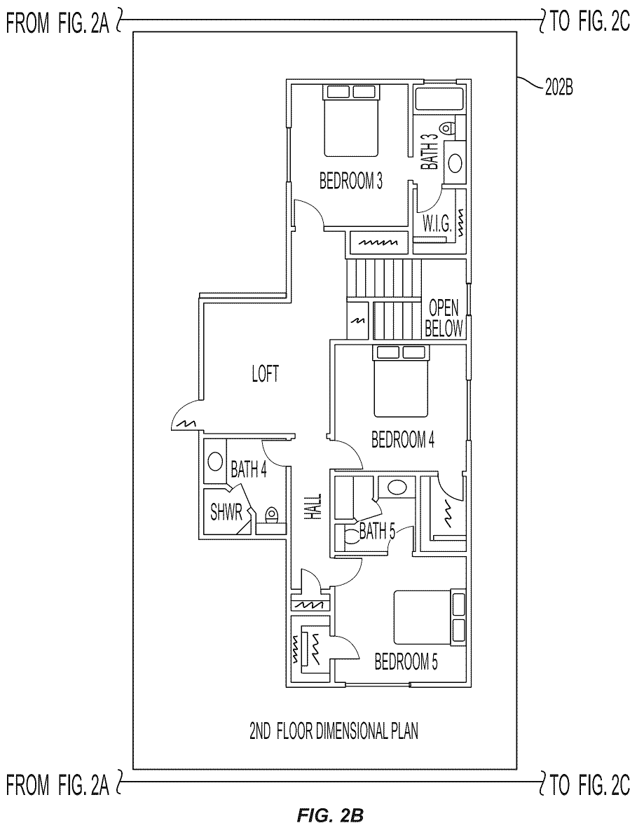

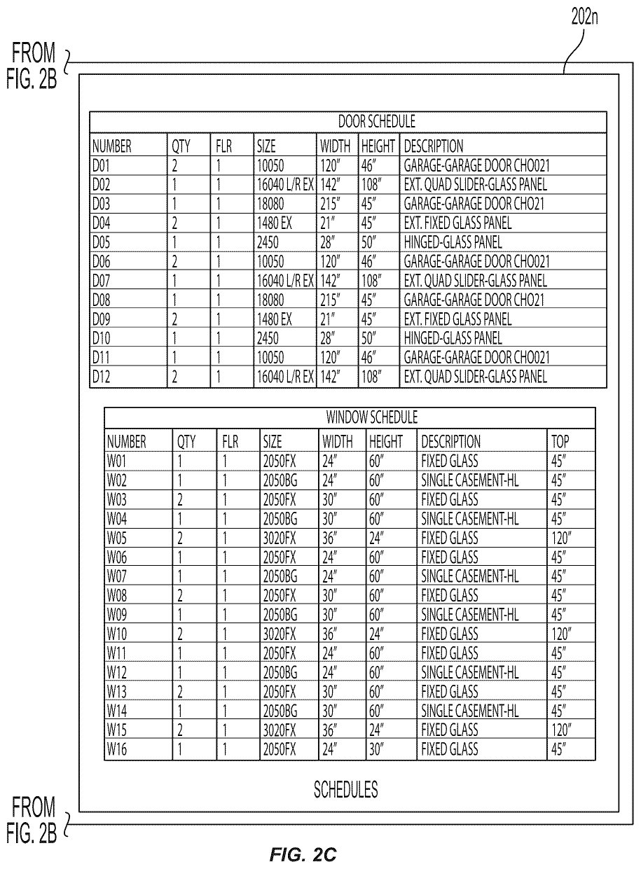

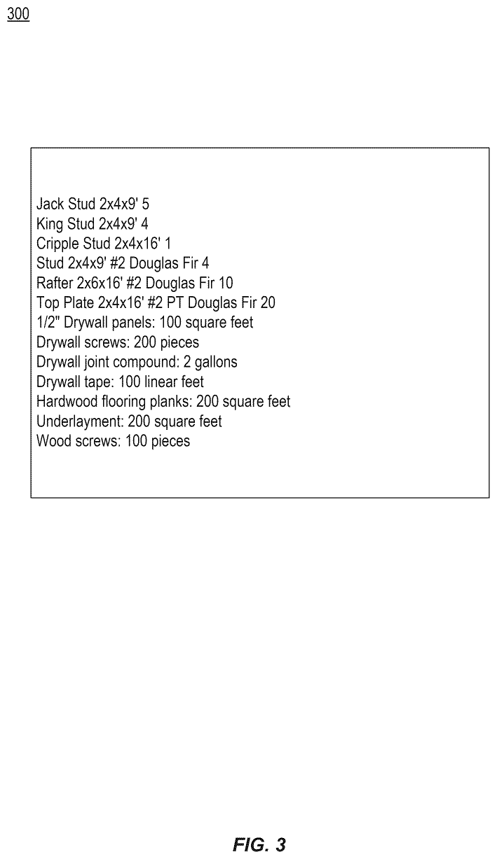

Turning now to the Figures, FIG. 1 depicts a system 100 for construction document analysis, in accordance with an aspect of the present disclosure. In the example depicted in system 100, a construction document 110 is provided to construction analysis system 130, which analyzes the construction document 110 using machine learning to generate takeoff 170. An example of construction document 110 is a blueprint or other document that includes construction-related information and/or drawings. An example of a construction document or blueprint is provided with respect to FIGS. 2A-C and an example of a takeoff is provided with respect to FIG. 3.

FIGS. 2A-C depict an example of a construction document 200, in accordance with an aspect of the present disclosure. Construction document 200 includes a detailed drawing of the project, precise dimensions, construction materials specified, placement of all components. The pages of construction document 200 may represent different considerations in for the associated construction project. For example, a first page may represent the walls, whereas the second page may represent electrical systems, and so forth. As depicted, construction document 200 multiple pages 202a, 202b, and 202n. As can be seen, page 202a depicts an electrical plan, 202b depicts a dimensional plan, and 202n depicts schedules. A schedule may include a building timeline outlining an order and duration of the project. Other pages and/or sections are possible.

As used herein, a “bill of materials takeoff” or a “takeoff” refers to a detailed list of all materials needed for a project by carefully measuring and calculating quantities directly from construction drawings. For example, returning to FIG. 1, takeoff 170 includes one or more bill of materials (BOM) 180a-n. Each BOM 180a-n includes a detailed list of all materials, components, parts, and assemblies required for a sub-category of the construction project. A first BOM 180a may include information regarding components needed for the roof, whereas BOM 180b may include information regarding components needed for the walls, and so forth.

FIG. 3 depicts an example of a bill of materials 300, in accordance with an aspect of the present disclosure. Bill of materials 300 may include quantities off materials needed for construction.

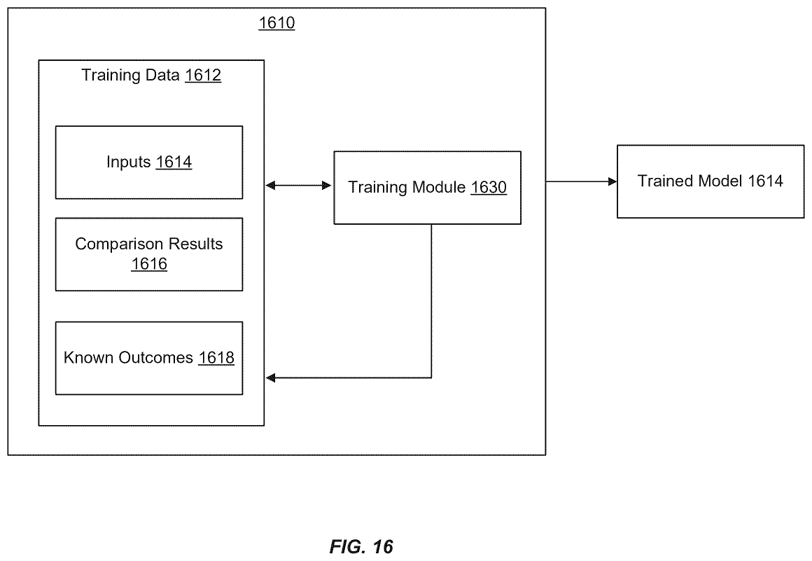

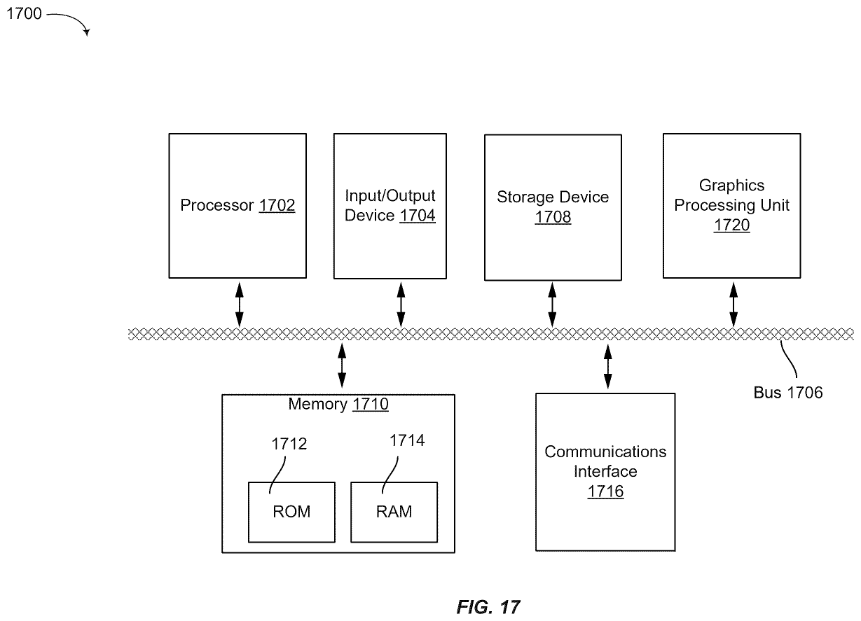

Returning to FIG. 1, construction analysis system 130 includes computer system 140, an example of which is depicted in FIG. 17, and one or more machine learning models 150a-n. Any of machine learning model 150a-n may execute on one or more cloud servers. As discussed further herein, each machine learning model 150a-n may be separately trained to perform one or more respective functions. Examples of such functionality include document page classification, identification of walls, identification of electrical components, and so forth. An example of training is discussed further with respect to FIG. 16.

In an example, computer system 140 provides pages of the construction document 110 to machine learning model 150a for page classification. Machine learning model 150a classifies the pages as walls, roofing, electrical, and so forth. Then, computer system 140 provides the classified pages to their respective models, e.g., 150b-150n. Each model identifies objects such as structural and non-structural features. The models may operate in parallel.

Continuing the example, machine learning model 150b is trained to identify objects such as walls and machine learning model 150c is trained to identify objects such as roof elements. Accordingly, the pages classified as including wall information are provided to machine learning model 150b and the pages classified as including roof drawings are provided to machine learning model 150c. Machine learning model 150b and 150c then each generate their respective outputs, each of which identify objects such as building elements. In some cases, a model generates one or more masks or bounding boxes that identify one or more objects.

The identified building elements, e.g., walls, roof elements, door and window openings, and so forth, arc analyzed by computer system 140. From the identified building elements, construction analysis system 130 creates takeoff 170, which includes one or more BOMs 180a-n. In some cases, an interactive canvas is presented on a display. The canvas may include walls, spaces, windows, doors, cased openings, textual information, and measurement scales. In some cases, a user can validate or modify the building elements.

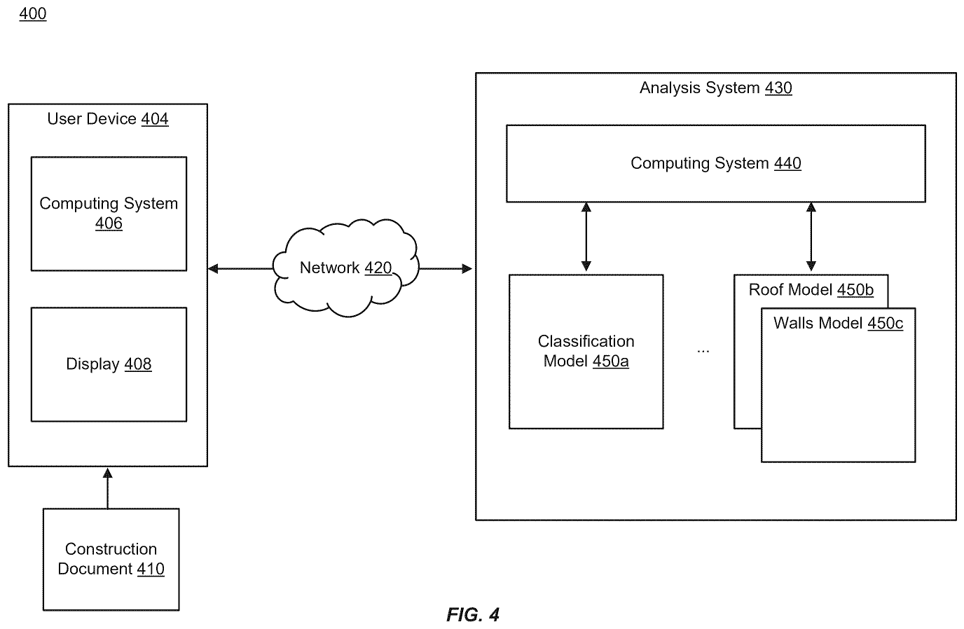

In some cases, the construction analysis system operates as a cloud-based server system. Such a system may include a web-based or application-based interface. A user may interact with construction analysis system the via a web or desktop application client. An example of such a system is depicted with respect to FIG. 4.

FIG. 4 depicts a client-server system 400 for using machine learning for construction document analysis, in accordance with an aspect of the present disclosure. In the example depicted in FIG. 4, client-server system 400, user device 404 (e.g., a client device) provides one or more construction documents 410 to analysis system 430 (e.g., a server device) via network 420. In turn, analysis system 430 analyzes construction document 410 and provides the results back via network 420 to user device 404.

User device 404 includes computer system 406 and display 408. An example of computer system 406 is depicted with respect to computer system 1700 of FIG. 17. An example of user device 404 is a phone, tablet, or computer system. Display 408 may be used to display the results generated by analysis system 430 and/or provide a mechanism via which a user may provide feedback or adjustments to the results. Examples of network 420 include wired and wireless networks, such as Examples of wireless communication include WiFi®, Cellular (e.g., 3G, 4G, LTE, 5G, etc.), Bluetooth® and so forth. Other examples are possible.

Analysis system 430 includes computer system 440, page classification model 450a, and additional machine learning models 440b-c. Analysis system 430 may be considered a server device. An example of computer system 440 is depicted with respect to computer system 1700 of FIG. 17.

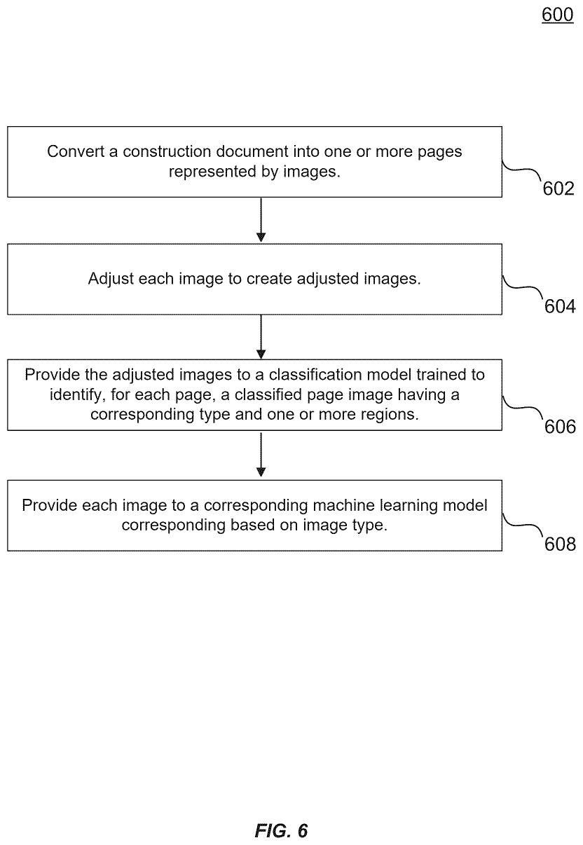

Classification model 450a is trained to identify a page type given a page input. For example, classification model 450a can determine whether a given page is structural, electrical, roofing, and so forth. An example of a process used to determine a page classification is discussed with respect to FIG. 6.

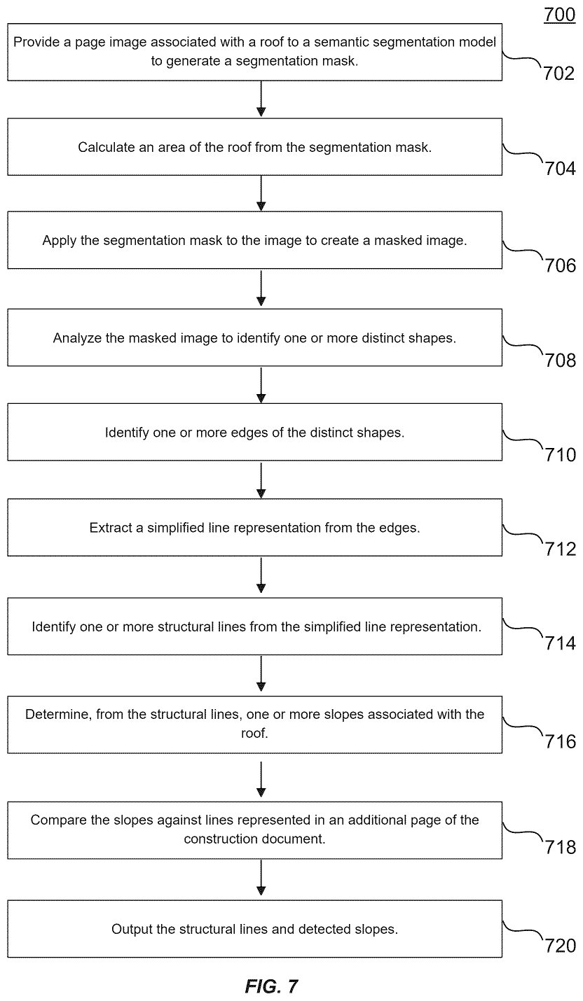

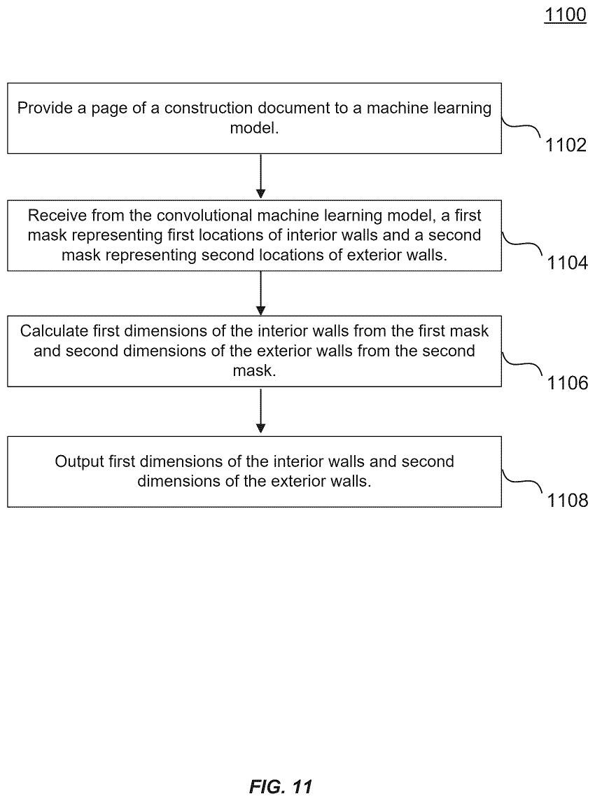

As discussed, certain aspects can use one or more specialized machine learning models to perform the functionality described herein. Each model may be trained independently on annotated datasets. Machine learning models 440b and 440c are specialized models. Roof model 450b is trained to determine, from a page identified by classification model 450a as illustrating roof information, one or more roof features. An example of a process used to determine a page classification is discussed with respect to FIG. 7. Walls model 450c is trained to determine, from a page identified by classification model 450a as illustrating wall information, one or more wall features. An example of a process used to determine a wall classification is discussed with respect to FIG. 11. Additional models are possible. In some cases, algorithmic approaches are used in conjunction with machine learning to identify objects.

Upon completion of inference of the models, various algorithms may be used to integrate the classified results. This integration merges data about walls, windows, doors, spaces, cased openings, textual information, and scale. The algorithms implement domain-specific rules provided by civil engineering experts to ensure structural coherence.

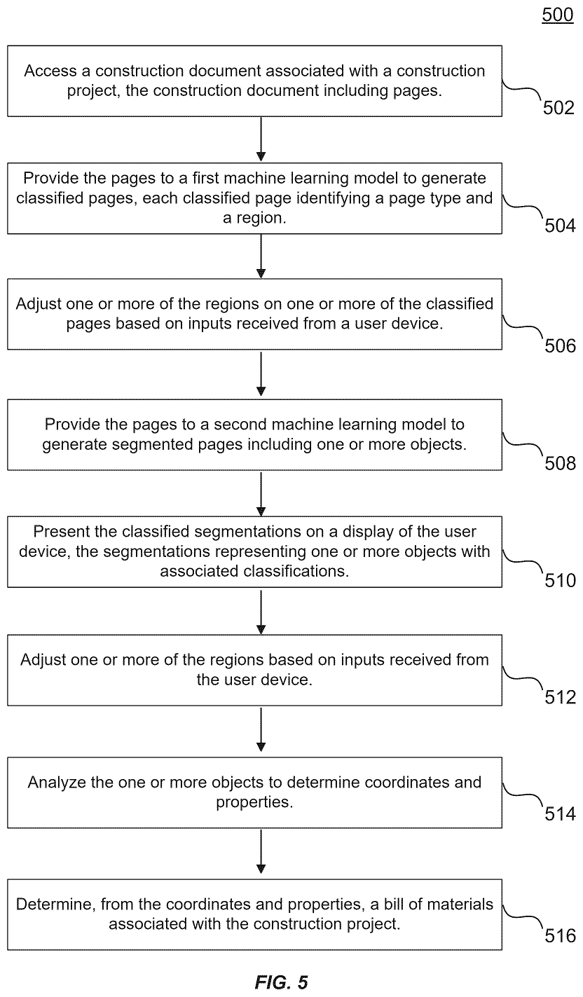

FIG. 5 depicts an example of a process 500 for using machine learning to analyze a blueprint document, in accordance with an aspect of the present disclosure. Process 500 is discussed with reference to FIG. 4 for illustrative purposes. But process 500 may be performed by any computer system. Further, while process 500 is discussed as having various blocks (e.g., operations), any individual block may be skipped and/or repeated. Further, any block of process 500 may be performed out-of-order relative to the order listed herein.

At block 502, process 500 involves accessing a construction document associated with a construction project. Examples of construction documents include construction document 200 and construction document 410. The construction document may include multiple pages. User device 404 accesses the construction document. For instance, computer system 406 executes an application or a web browser, with which the user may interact with analysis system 430. For example, a user operating the user device 404 may cause a construction document to be uploaded, transmitted via network 420, and accessed by computer system 406, where the document is analyzed.

At block 504, process 500 involves providing the pages to a first machine learning model to generate classified pages. Non-limiting examples of the first machine learning model include convolutional neural networks (CNNs), a transformer-based vision models, and region-based CNN (R-CNNs).

In some cases, the pages may be provided as images, e.g., bitmaps, to the first machine learning model. In other cases, the pages may be further translated into another numerical representation, such as a feature vector, prior to being provided to the first machine learning model. In some cases, prior to being provided to the machine learning model, the construction document may be processed by optical character recognition (OCR), enabling the machine learning models to analyze text within the construction document.

Continuing the example, analysis system 430 provides the document to classification model 450a to identify a respective page type, or a classification, for each page. Each classified page identifies a page type and a region. Continuing the example, each page image is assigned a label corresponding to the page type. Non-limiting examples of labels include “Cover,” “Electrical,” “Elevation,” “Flat Roof,” “Foundation,” “Mechanical,” “Notes,” “Plumbing,” “Job Site,” “Slope Roof,” and “Structural.” A flat roof has measurements that would be identical as measured from the ground. By contrast, a roof with a pitch or a slope has a length that is higher than a corresponding flat roof element due to the rise and run.

Classification model 450a may identify regions. A region represents part of the page. In some cases, only one region is identified. In other cases, multiple regions may be identified.

Each identified region may have a corresponding type that may be different from types of other regions. For instance, the model may identify that a first region relates to roofing whereas a second region relates to electrical systems.

In some cases, the classified pages are provided to user device 404 for review and are displayed on display 408. A user operating the user device 404 may interact with computer system 406 by using a mouse, keyboard, touch screen, etc., and make one or more edits to the classified pages. Examples of edits include re-classifying the page, editing or removing one or more objects on the page, removing a particular page from consideration, and/or otherwise providing feedback to the system.

At block 506, process 500 involves adjusting one or more of the regions on one or more of the classified pages based on inputs received from a user device. Continuing the example, the identified pages and regions within the page created by analysis system 430 are provided via network 420 to user device 404. The pages and/or regions may be displayed on display 408. Then, user device 404 may visualize the pages and/or regions for a user who may instruct the system to make any necessary edits or changes.

For example, a user may identify a region within a classified page that contains irrelevant or incorrectly classified information. Then the user may tag the region and provide the feedback to user device 404. This may improve the machine learning model. For example, and page may be identified as including electrical information but in fact the page identifies only structural information. In this case, the user may correctly identify the page and provide such information back to the system. In another example, the user may identify additional information that was not classified by the machine learning model. In this case, the user provides feedback to the system identifies which then correctly the additional information. Any additional or corrected information received from user device 404 is processed by the system. In some cases, the regions and/or classified pages are not presented on a display and user feedback is not solicited. In these cases, block 506 may be skipped.

At block 508, process 500 involves providing the pages to a second machine learning model to generate segmented pages including one or more objects. As discussed, system 400 may use additional machine learning models, each of which is trained for a specific purpose such as identifying objects of a specific type. Each object may correspond to one or more building elements. An example of the operations performed in block 508 is discussed with respect to process 600 of FIG. 6.

In an example, roof model 450b may be trained to detect roof information, whereas walls model 450c may be trained to detect wall information. While training may occur offline, the inference phases of the models may occur in parallel. For example, the roof model 450b may detect roof elements in parallel with walls model 450c detecting wall information. Other examples are possible.

Continuing the example, a page image of a particular type is provided to a model that is trained to analyze that particular type of page image. In some cases, the image is provided directly to the model. In other cases, the classified page images are converted to another numerical representations such as a feature vector.

In some cases, instance segmentation is used. Instance segmentation is a computer vision technique that recognizes each object instance of a particular category as a distinct entity. In other words, if there are multiple objects of the same class in an image, instance segmentation may identify and delineate each object separately. This is particularly beneficial in complex images where objects of the same class overlap or are in close proximity.

In some cases, the system 430 may detect a scale and intended to be used within the construction drawings. A separate machine learning model may be used for this purpose. The detected scale is used throughout the process to correctly identify a size of objects.

At block 510, process 500 involves presenting the classified segmentations on a display of the user device. The segmentations represent one or more objects with associated classifications. For example, a roof segmentation may include multiple objects or roof elements, such as planes, connectors, and so forth. A wall segmentation may include objects such as wall segments.

In some cases, the classified segmentations may be displayed for the user. The presentations may be a “canvas” type presentation, The results are composited onto an interactive canvas. In some cases, color may be used. In this case, the identified walls may be color-coded by type (exterior vs. interior). The identified spaces may be highlighted, each space labeled with extracted names and heights. Scale references display real-world units (metric and/or imperial). In some cases, key elements (walls, interior, exterior), spaces (with names, heights), scale lines (real-life measurements) may be highlighted. In some cases, detailed blueprint components (wall framing, floor, ceiling, roof joists, exterior elevations, windows, doors, insulation, drywall, interior finishes) may be displayed. In some cases, a screen toolbar for modifying, adding, removing, selecting, resizing elements may be used.

In some cases, a toolbar displayed on display 408 allows a user to add, remove, resize, or reclassify elements. Changes may be reflected immediately, ensuring updated calculations for framing, insulation, etc., on the display 408. Once the user is satisfied with the results, the analysis system 430 may finalize the data, generating a structured record of all building elements.

At block 512, process 500 involves adjusting one or more of the regions based on inputs received from the user device. Any user inputs received at block 510 are processed and may cause one or more regions of one or more pages to be adjusted. In some cases, user feedback is not solicited and blocks 510-512 are skipped.

At block 514, process 500 involves analyzing the one or more objects to determine coordinates and properties. Each object, or building element, may have one or more associated coordinates. For instance, a section of wall may have a first set of coordinates (e.g., x₁, y₁) and a second set of coordinates (e.g., x₂, y₂). In some cases, an object may have four or more sets of coordinates, for example, in the case of a square, rectangle, parallelogram, etc. In other cases, an object may have more than four sets of coordinates. From the coordinates, dimensions such as length and orientation may be determined.

Each building element may one or more associated properties. Non limiting examples of properties include identification as a roofing element, a wall section, a door opening, a window opening, and so forth. In some cases, properties may include an identification of internal or external. As discussed below, a structured record may be generated from the building elements. The structured record may include a list of objects within the classified page, associated coordinates, and associated properties.

At block 516, process 500 involves determining, from the dimensions and the properties, a bill of materials associated with the construction project. A bill of materials may include total count of walls, windows, and doors, etc. Such a list includes essential items such as lumber for headers and footers, as well as materials needed for assembly and finishing. Additional items on a list may include drywalls, fasteners, joint compounds, nails, screws, drywall tapes, insulation, primer, and paint, ensuring that every aspect of material requirement may be considered.

Once the building elements are identified, the system can provide a detailed estimate of the required materials. For instance, each building element or object may have an associated quantity of one or more materials such as lumber that are needed to construct the object. For example, a wall object may have width and height dimensions and an associated thickness. The thickness may be determined by whether the wall object is an interior or exterior wall, and/or based on annotations in the original construction document. A wall object may cause a specific type of lumber, e.g., 2 inch×4 inch lumber or 2 inch×8 inch lumber, to be needed. Other options are possible. For instance, if the wall segment represents a cased opening, then additional materials may be necessary such as a beam to hold weight above the opening, and so forth, then consider different requirements based on structural support needed. Once each of the quantities of materials are determined, then the quantities may be summed to provide a total.

Assumptions may be made about the required materials such as considering local requirements. Any assumptions include ensuring that the resulting construction would be in compliance with local code, follows the directions provided by the architect or builder as provided on the blueprint (as identified by the techniques disclosed herein) and selects from material options that are included in a database. In some cases, each component may have more than one suitable option.

Structural engineering principles may be applied at block 516. Some elements within the bill of materials may be derived using additional task-specific machine learning models. For instance, in some cases, the system can use a model that predicts necessary doors and windows for the project.

The system can display the total number of doors and windows, sorted by their specific categories. These categories include single windows, double windows, triple windows, custom windows, single-fold doors, double-fold doors, single doors, and French doors. This categorization allows for a more tailored and accurate material estimation, tailored to the unique needs of each project. In some cases, the system may may filter the takeoff based on category, for example, lumber, roofing, electrical, plumbing, foundation, flooring, windows and doors, and ceiling. A user may provide additional information using a text box area and also upload extra documentation such as schedules. In an aspect, system 430 can export the materials list to an external file and/or system. The final data can be exported in multiple formats (JSON, PDF, CSV), facilitating integration with enterprise resource planning (ERP) or procurement systems.

In an aspect, system 430 can generate a cost estimation for the project. For instance, the system 430 can request and obtain pricing from retail partners. In some cases, the user may add a waste factor to the analysis. This allows for a percentage increase in materials to be added to cover any waste, for example, due to cutting or damaged goods.

FIG. 6 depicts an example of a process 600 for using machine learning to classify pages of a construction document, in accordance with an aspect of the present disclosure. Process 600 is discussed with reference to FIG. 4 for illustrative purposes. But process 600 may be performed by any computer system. Further, while process 600 is discussed as having various blocks (e.g., operations), any individual block may be skipped and/or repeated. Further, any block of process 500 may be performed out-of-order relative to the order listed herein.

At block 602, process 600 involves converting a construction document into one or more pages represented by images. The construction document may be a vector drawing such as Portable Document Format (PDF) or Postscript (PS), or an image such as a Joint Photographic Expert Group (JPEG) image. In some cases, vector drawings are converted to images. In an aspect, the pages are separated from the document prior to being provided to the classification model 450a.

At block 604, process 600 involves adjusting each image to create adjusted pages. Various adjustments to the images are possible prior to the images being provided to classification model 450a. For example, images from the pages of the document may be normalized to a specific measure of density (e.g., 300 dots per inch). In an aspect, the images are padded or cropped as necessary to fit a specific shape and/or size. A standardized aspect ratio may be applied to all page images. A standardized color balance may is applied to the pages.

System 430 then provides the extracted pages document to the classification model, e.g., classification model 450a. In turn, classification model 450a processes each page and outputs a type for each page. Non-limiting examples of page types or classifications include structural, electrical, mechanical, roofing, and so forth. Classification model 450a can employ feature extraction, transforming each region of the page into a fixed-size vector of features. This transformation distills the essential characteristics of each region, regardless of the original dimensions of the image. Classification model 450a then determines whether the region contains a specific area of interest within the blueprint.

In some cases, bounding block regression is used. For regions of the image that encompass a target area, classification model 450a can adjust the coordinates of the bounding box such that the correct area is analyzed. A selective search algorithm may be applied to the page to determine bounding box candidates, or region proposals. These proposals are essentially candidate areas that might contain relevant features or objects within the page.

In some cases, classification model 450a is trained to identify primary objects (e.g., roofing clement, window, door, and so forth) and is also trained to positively identify secondary objects that are unwanted so that the secondary objects may be removed from analysis. This augments clarity and precision of the analysis. This approach may be conducted in a second phase or iteration of the model. In this secondary phase, the model, trained to recognize non-essential elements like blocks of text and tables, is deployed. This model is adept at identifying and marking these elements, which are not pertinent to the structural analysis. These identified elements are then removed.

At block 606, process 600 involves providing the adjusted images to a page classification model trained to identify, for each page, a classified page having a corresponding type and one or more regions. Types include electrical elevation mechanical and so forth.

In some cases, a page may have only one region. But in other cases, a page may have two or more regions where each region relates to different material. For example, a first region may include electrical information whereas a second region may include mechanical information. Identifying different regions therefore allows the system to process all the available information of the construction document. If a single page is identified to have multiple distinct sections (e.g., part electrical, part structural), the system and/or the user can duplicate or split the image region to separate them for more accurate downstream inference.

The page classification model may be trained using a comprehensive training process. For example, supervised, non-supervised, or other types of learning may be used. In an example, the training process commences with construction document images being curated into a specialized dataset. This training utilizes a diverse set of labeled pages, allowing the model to recognize a range of page types, from simple line drawings to complex schematics. Here, the pages are annotated with ground truth data. Each image is assigned a label corresponding to the page type, such as “Cover,” “Electrical,” “Elevation,” “Flat Roof,” “Foundation,” “Mechanical,” “Notes,” “Plumbing,” “Job Site,” “Slope Roof,” or “Structural.” These labels may be verified by human annotators or by other means. The training process may use with optimized hyperparameters. In some cases, the training data set is validated to ensure that the model meets performance metrics before deployment. Once deployed, the model is integrated into the software APIs, where the model performs real-time analysis of incoming blueprints during the initial processing phase.

In some aspects, additional refinements are provided to improve page classification model performance. Various augmentations (brightness, contrast adjustments, slight rotations, scaling, noise addition) are introduced to improve model robustness. Training may involve known outputs, e.g., known classifications of pages. During backpropagation, the model parameters are adjusted such that an error is reduced with respect to the known classification of the pages. A final dataset may be then split into training, validation, and test sets. Once the model achieves target accuracy on validation data, it is deployed in a containerized environment for inference.

Returning to FIG. 6, at block 608, process 600 involves providing each classified page image to a corresponding machine learning based on image type. As discussed, because each model may be trained separately to identify specific construction information the classified page images are therefore provided to corresponding models.

The page classification model may be a convolutional neural network (CNN). In a CNN, various layers use specialized filters to extract essential features from the document pages. Examples of features include lines, symbols, and textural patterns. Then, one or more pooling layers reduce spatial dimensions of these extracted features, thereby enhancing the model's efficiency and its ability to handle variations in scale and orientation. The fully connected layers of the model interpret the extracted features and classify each page into a respective type. Activation functions within these layers introduce non-linearity, enabling the model to learn and identify complex patterns from the blueprint data.

In an aspect, to ensure accuracy, Non-Maximum Suppression (NMS) may be used. This technique is vital for eliminating redundant and overlapping bounding boxes, thereby retaining only the most accurate bounding box for each detected area.

FIG. 7 depicts an example of a process 700 for using machine learning to roof data from pages of a construction document, in accordance with an aspect of the present disclosure. Process 700 may be performed by any computer system. Further, while process 700 is discussed as having various blocks (e.g., operations), any individual block may be skipped and/or repeated. Further, any block of process 700 may be performed out-of-order relative to the order listed herein.

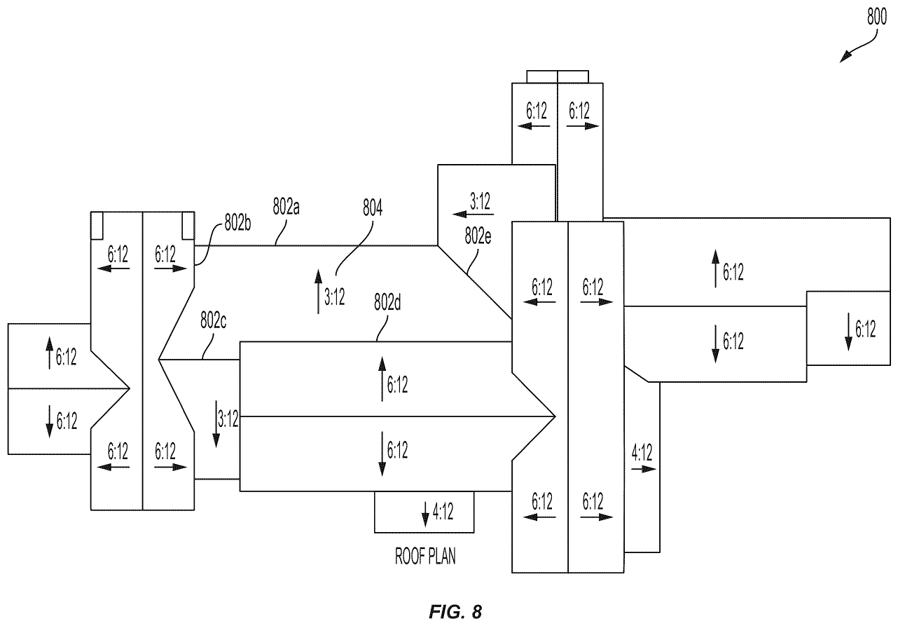

Process 700 receives as input a page associated with a roof. FIG. 8 depicts an example of a page image associated with a roof, for instance, determined via a process 600 of FIG. 6. To form accurate estimates of construction costs for roofing materials, the slopes and areas are identified. This step isolates the blueprint image that contains sloped roofing details, ensuring that subsequent operations work exclusively on the intended architectural data.

FIG. 8 depicts an example of a page 800 depicting roofing information, in accordance with an aspect of the present disclosure. As depicted, page 800 includes multiple roof elements, each roof element having a respective slope and a respective area. Page 800 includes structural lines 802a-e and corresponding area 804. As can be seen, structural lines 802a-802e collectively form a parallelogram-like shape on the roof.

Returning to FIG. 7, block 702, process 700 involves providing a page image associated with a roof to a semantic segmentation model to generate a segmentation mask. This semantic segmentation model is trained to identify slopes in a roofing diagram. The segmentation model can produce a pixel-wise segmentation mask, which is then used to calculate a total roof area.

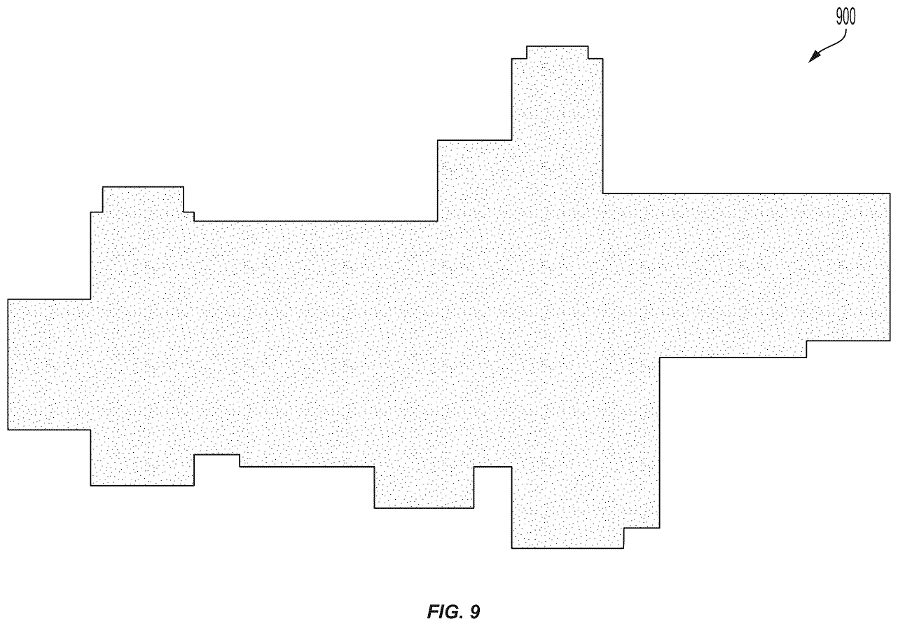

Analysis system 430 can count a number of pixels within the object area that are classified as roof and convert pixel counts into physical area measurements using a scaling factor. As discussed, a scaling factor can be identified by using machine-learning or algorithmic techniques. An example of a segmentation mask is depicted in FIG. 9.

FIG. 9 depicts an example of a mask 900 illustrating a roof illustration of a construction document, in accordance with an aspect of the present disclosure. As can be seen the shaded area in FIG. 9 represents locations of roof. By contrast, where there are no dark regions, no roof has been identified by the model.

Returning to FIG. 7, at block 704, process 700 involves calculating, from the segmentation mask, an area of the roof. Continuing the example, the system calculates the area of the roof from the segmentation mask. Each unit for example pixel of the segmentation mask represents a specific amount of area.

At block 706, process 700 involves applying the segmentation mask to the image to create a masked image. When the segmentation mask is applied to the image, a masked image that includes only roofing elements is created.

At block 708, process 700 involves analyzing the masked image to identify one or more distinct shapes. The distinct shapes are shapes that are created by the structure of the roof. Examples of distinct shapes include rectangles, squares, parallelograms, and irregular shapes.

In some cases, after the initial roof area computation, the system cleans the roof image to enhance structural features and prepare the image for geometric analysis. For example, an image processing algorithm can detect and remove non-essential gray lines and filled regions. These elements, often artifacts of the drafting style of the construction document, may be eliminated to reduce visual noise and isolate the architectural elements.

Each distinct shape or region in the image may be tagged. For instance, if the page image represents sloped roofs, then the model may identify rafters, ridges, hips, caves, and valleys from the image. This approach facilitates segmentation by clearly distinguishing one architectural element from another, thereby simplifying the downstream analysis of the structure. In some cases, a user may adjust the identified elements. In some cases, each distinct shape or region in the image is filled with a unique color or pattern and presented to the user for visualization.

At block 710, process 700 involves identifying one or more edges of the distinct shapes. For example, the system identifies four edges of a rectangle. Here, a redrawing algorithm is applied to trace the prominent edges of each identified region. From these traced edges, a skeleton, or a simplified line representation, is extracted using edge detection and morphological operations. This consolidates the image into its core structural framework and improves the accuracy of subsequent line detection. The output may be a cleaned image complemented by a skeletal representation that preserves the essential geometry of the roofing design.

At block 712, process 700 involves extracting, from the edges, a simplified line representation. With simplified line representation, a line detection module may be employed. The line detection module may use techniques such as the Hough Transform (HT) or specialized deep learning-based line extraction algorithms to accurately detect and identify structural lines.

Using the resulting simplified line representation, the orientation of the detected lines is analyzed. By calculating line angles and relative positions, the system identifies and classifies sloped regions within the roofing area.

Analysis system 430 can determine slopes of the roof by mapping out the contours and determining the angles. As can be seen in FIG. 8, typically, slopes of roofing segments are provided on the diagram. However, the areas of the roofing segments are not provided. Each slope may represent a different bill of material or amount of material based on the width and length of the element and pitch of the slope. Disclosed techniques can identify the slopes automatically, identify an associated material applied, and can determine the actual length of the slope and lines based on the roof pitch.

At block 714, process 700 involves identifying one or more structural lines from the simplified line representation. Examples of structural lines are lines 802a-e of FIG. 8.

At block 716, process 700 involves determining, from the structural lines, one or more slopes associated with the roof. The contours and angles may then be cross-referenced with the cleaned structural features to verify their authenticity as roofing slopes based on location. When the slope is determined and the line to which the slope is associated is determined, then analysis system 430 can inform the model to associate the slope with the line.

At block 718, process 700 involves comparing the slopes against lines represented in an additional page of the construction document. The additional page includes one or more structural diagrams. This can help validate that predictions of the model are correct. For instance, if some manipulation is determined to be needed, the model output and/or model itself may be corrected.

At block 720, process 700 involves outputting the structural lines and detected slopes. Here, the structural lines may be represented by one or more pairs of coordinates. The slopes may be represented by ratios, fractions, or some variant thereof.

The outputs from the roof area estimation, line detection, and slope identification processes may be aggregated. This structured output includes detailed spatial coordinates and geometric descriptors for each line detected, specific measurements and classifications for identified slopes, including angle values and polygonal representations of the sloped areas, additional metadata such as confidence scores, conversion factors (e.g., from pixel measurements to physical dimensions), and other ancillary data necessary for downstream applications. An example of structured output is shown below for illustrative purposes:

```
{
  “Type”: “BlueprintProAI.Roofing.Application.Events.PredictRoofingSuccess”,
  “RequestId”: “324d1b63-3662-4d53-bf11-f585f1d38bd7”,
  “CorrelationId”: “74224acc-36bb-4938-9fa0-16a3a4087fdb”,
  “UserId”: “59e0e4f0-105d-4545-b68c-bd8eb697fe88”,
  “Payload”: {
    “FileId”: “7869a74c-88c3-4f8e-a9f5-2e754dd8b6ec”,
    “Square5120Id”: “resized/7869a74c-88c3-4f8e-a9f5-
2e754dd8b6ec/5120_output_6.png”,
    “Objects”: [
      {
        “CategoryName”: “area”,
        “Segments”: [
            {
              “X”: 2831,
              “Y”: 176
            },
            {
              “X”: 2831,
              “Y”: 234
            } ...
          }
          }
```

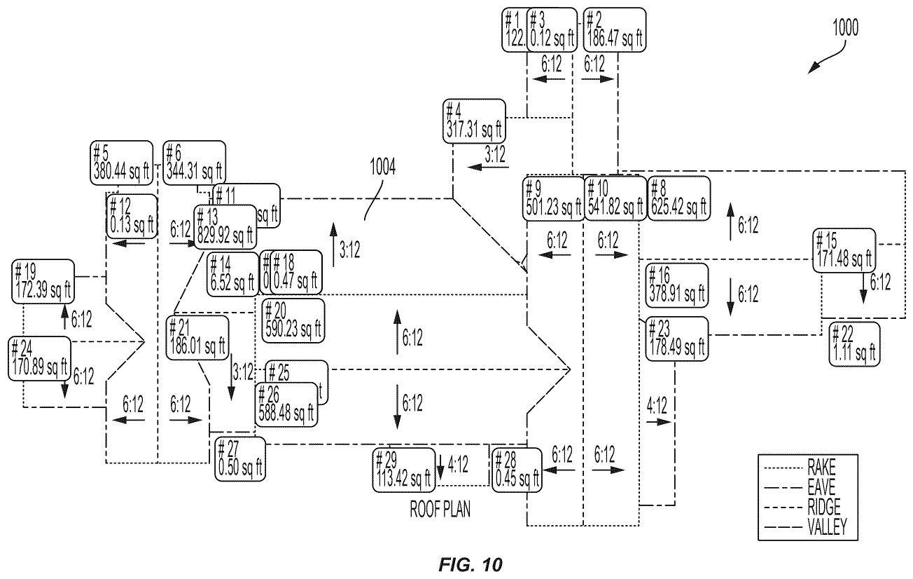

FIG. 10 depicts an example of an output illustrating a roof 1000 within a construction document, in accordance with an aspect of the present disclosure. As can be seen, roof 1000 includes multiple areas, including area 1004 (corresponding to area 804 of page 800). Each area is annotated with details such as area and slope. In some cases, the algorithm may be tuned to handle the typical variations found in blueprint images (e.g., line thickness variability and noise), ensuring that detected lines correspond accurately to actual roofing elements.

As depicted, each boundary is shaded according to categories, which may include eaves, hips, valleys, ridges, and rakes. Other examples are possible. An eave is the lower edge of a roof that overhangs the exterior walls. An eave helps direct water away from the building. A hip is an external angle where two sloping roof surfaces meet, typically forming a ridge. Hips are found in hip roofs. A valley is an internal angle where two sloping roof surfaces meet, directing water runoff to gutters. A ridge is the highest horizontal line where two roof planes meet at the peak. A rake is a sloped edge of a gable roof extending from the eave to the ridge.

FIG. 11 depicts an example of a process 1100 for using machine learning to identify information about walls from pages of a construction document, in accordance with an aspect of the present disclosure. Process 1100 may be performed by any computer system. Further, while process 1100 is discussed as having various blocks (e.g., operations), any individual block may be skipped and/or repeated. Further, any block of process 1100 may be performed out-of-order relative to the order listed herein.

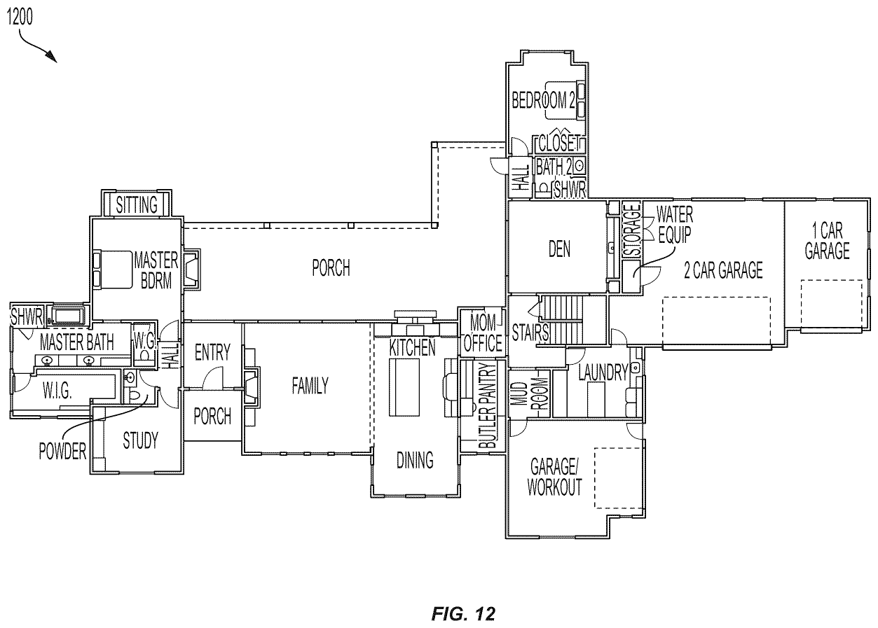

Process 1100 receives as input any pages that are identified as structural pages. From these structural pages, the pages containing wall information are identified and selected. Pages that do not contain actual structural elements are not considered. In some cases, the received page is preprocessed to clean up the document and to improve machine learning performance. The structural pages include images that contain detailed line drawings, text annotations, and symbols. An example of an input to process 1100 is depicted in FIG. 12.

FIG. 12 depicts an example of a structural document 1200, in accordance with an aspect of the present disclosure. As can be seen, structural document 1200 includes walls, dimensions, and room labels.

In some cases, prior to inference, the page images are normalized (pixel intensity scaling, contrast normalization) and are resized to a standardized input dimension. This ensures that the spatial features (e.g., lines representing walls) are consistent across the dataset.

The machine learning model may be trained using supervised, unsupervised, or other learning techniques. In an example, various selected images are incorporated into a specialized dataset where expert annotators precisely mark and differentiate between exterior and interior walls. A thorough review process validates annotation accuracy before the dataset is exported for model training. Multiple augmentation techniques are applied to improve model robustness, training the model to recognize subtle differences between exterior and interior walls across various architectural styles and wall representations. The trained model undergoes precision testing to establish optimal parameters for consistent inference. A combination of losses is used during training including classification loss, which may be a cross-entropy or focal loss to discriminate between wall types, bounding box regression loss, which may be an Intersection over Union (IoU)-based or Least Absolute Deviations (L1) loss to refine spatial predictions, and a mask loss: often a dice coefficient or binary cross-entropy loss that enforces pixel-level accuracy between the predicted mask and the annotated ground truth. Results may be structured into standardized JSON format for downstream processing, ensuring seamless integration with other system components.

At block 1102, process 1100 involves providing a page of a construction document to a machine learning model. Examples of a suitable machine learning model include a CNN and an image segmentation model. The model may be trained to identify one or more wall segments and create a one or more masks that may be processed to obtain dimensions of interior and/or exterior walls.

In an example, selected images may be incorporated into a specialized dataset, which may be annotated. The training process is reviewed to validate annotation accuracy before the dataset is exported for model training. Multiple augmentation techniques may be applied to improve model robustness, training the model to recognize subtle differences between exterior and interior walls across various architectural styles and wall representations. The model may use hierarchical feature learning, which employs a series of convolutional layers to extract features at multiple scales. Early layers capture low-level features (edges, line segments), while deeper layers encode higher-level semantic features (patterns indicative of wall structures). The model is designed to maintain high spatial resolution, which helps with detection of the thin, elongated structures typical of architectural walls.

In some cases, features having different scales are merged. A feature pyramid network (FPN) or a path aggregation network (PANet) is integrated to merge features having different scales. This ensures that both large exterior walls and finer interior walls are captured effectively.

In some cases, attention mechanisms or residual connections may be employed to further emphasize salient architectural features while suppressing noise from extraneous details (e.g., annotations or grid lines). In some cases, a unified prediction framework may be used. This includes using includes both bounding box prediction and instance segmentation occurring simultaneously. This is achieved by extending the detection head with an additional segmentation branch.

In some cases, anchor-based detection is used. Here, the detection head divides the image into a grid, assigning each cell responsibility for predicting multiple candidate bounding boxes. These predictions include bounding box coordinates that represent location and extent of a potential wall segment, classification scores that indicate whether the predicted region corresponds to an exterior wall or an interior wall, and a pixel-level mask. In some cases, an entire image may be processed in a single forward pass, significantly reducing inference time while maintaining high accuracy. In some cases, to resolve overlapping predictions, non-maximum suppression (NMS) is applied. This helps ensure that each physical wall is represented by a single, coherent detection.

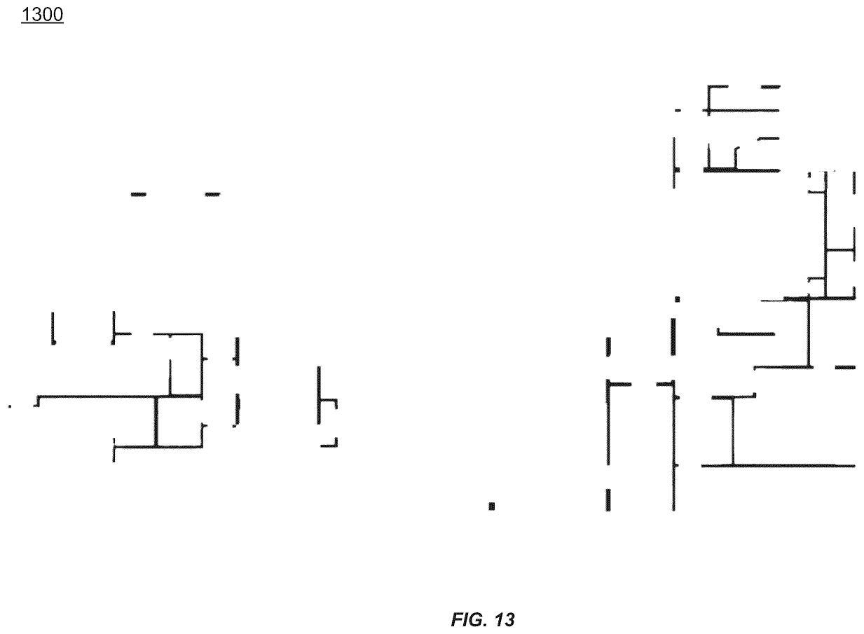

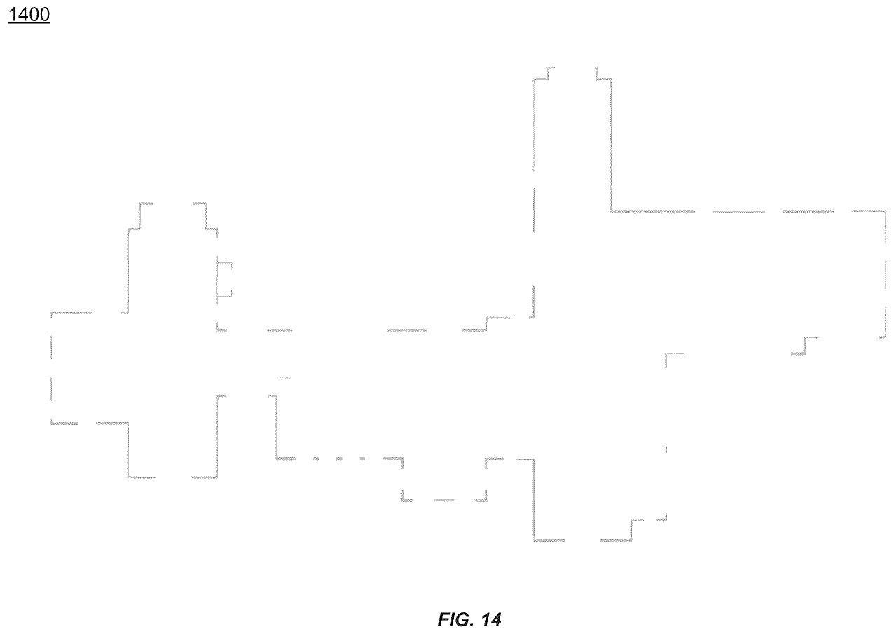

At block 1104, process 1100 involves receiving from the convolutional machine learning model, a first mask representing first locations of interior walls and a second mask representing second locations of exterior walls. With convolutional layers, for example, with deconvolution and up-sampling operations, a binary mask that illustrates a shape of the wall may be produced. An example of mask representing interior walls is depicted in FIG. 13 and an example of a mask representing exterior walls is depicted in FIG. 14.

FIG. 13 depicts an example of a mask 1300 identifying interior walls, in accordance with an aspect of the present disclosure. FIG. 14 depicts an example of a mask 1400 identifying exterior walls, in accordance with an aspect of the present disclosure. In some cases, the output segmentation masks are overlaid on the original blueprint image. Each detected instance (wall) is color-coded, producing a clear visual representation that highlights both exterior and interior walls.

At block 1106, process 1100 involves calculating first dimensions of the interior walls from the first mask and second dimensions of the exterior walls from the second mask. Here, a scaling factor between number of pixels and length or distance may be used.

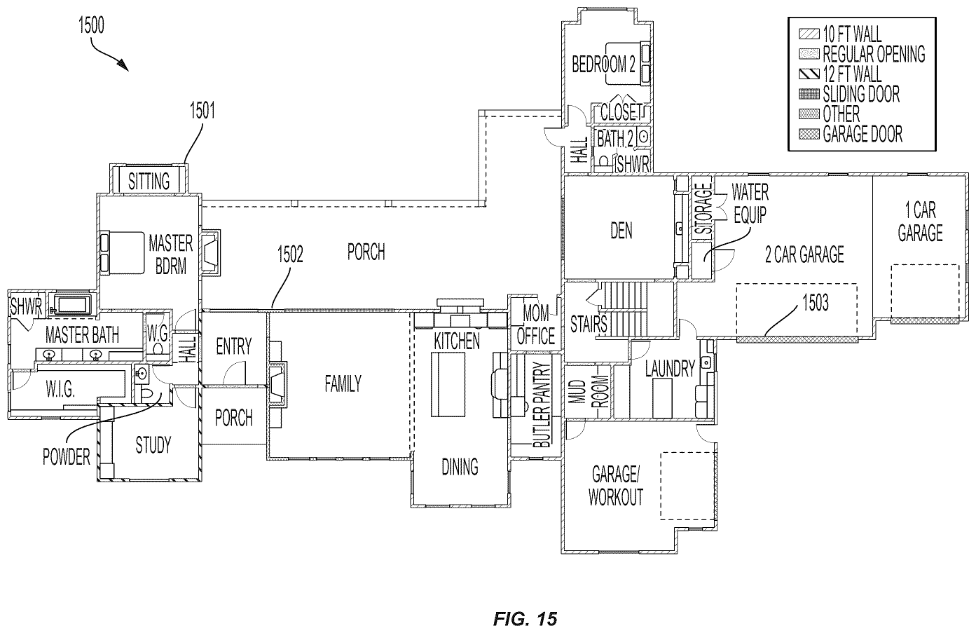

At block 1108, process 1100 involves outputting first dimensions of the interior walls and second dimensions of the exterior walls. A structured output is generated that includes detailed metadata for each detected wall instance coordinates and polygon vertices that include precise spatial data outlining the wall's shape; classification labels that distinguishing exterior from interior walls, confidence scores that are quantitative measures of detection certainty, and additional attributes including wall dimensions, orientation, and spatial relationships, facilitating downstream integration with a computer-aided design (CAD) or a building information modeling (BIM) system. The output may be visualized, an example of which is depicted in FIG. 15.

FIG. 15 depicts an example of a final wall visualization 1500 derived from classifications of a machine learning model, in accordance with an aspect of the present disclosure. As can be seen, visualization 1500 includes various annotations relative to the input plan as shown in FIG. 12. For instance, visualization 1500 identifies the classified wall elements (e.g., via shading or hatching).

As depicted, walls of height 10 feet, 12 feet, and other heights are identified. Additionally, regular openings, sliding door openings, and garage door openings are identified. Other classifications and visualizations are possible. The differences in object classifications can result in different materials and/or amounts of materials being required, therefore, the final bill of materials is created based on these classifications. Wall 1501 is a 10-foot wall, 1502 is a wall of other height (i.e., not 10 foot or 12 foot), and 1503 represents a garage door.

A detailed example of a takeoff is shown in the table below:

| # | Material | Quantity | Unit |
|---|---|---|---|
| 1 | Jack Stud 2 × 4 × 9′ | 8.00 | PCS |
| 2 | Jack Stud 2 × 6 × 9′ | 14.00 | PCS |
| 3 | Jack Stud 2 × 4 × 10′ | 94.00 | PCS |
| 4 | Jack Stud 2 × 6 × 10′ | 76.00 | PCS |
| 5 | Jack Stud 2 × 8 × 10′ | 12.00 | PCS |
| 6 | Jack Stud 2 × 4 × 12′ | 2.00 | PCS |
| 7 | Jack Stud 2 × 6 × 12′ | 12.00 | PCS |
| 8 | Jack Stud 2 × 8 × 12′ | 2.00 | PCS |
| 9 | Jack Stud 2 × 6 × 16′ | 22.00 | PCS |
| 10 | King Stud 2 × 4 × 9′ | 8.00 | PCS |
| 11 | King Stud 2 × 6 × 9′ | 16.00 | PCS |
| 12 | King Stud 2 × 4 × 10′ | 96.00 | PCS |
| 13 | King Stud 2 × 6 × 10′ | 90.00 | PCS |
| 14 | King Stud 2 × 8 × 10′ | 16.00 | PCS |
| 15 | King Stud 2 × 4 × 12′ | 2.00 | PCS |
| 16 | King Stud 2 × 6 × 12′ | 12.00 | PCS |
| 17 | King Stud 2 × 8 × 12′ | 2.00 | PCS |
| 18 | King Stud 2 × 6 × 16′ | 24.00 | PCS |
| 19 | Board 2 × 10 × 12′ | 1.00 | PCS |
| 20 | Plywood 4 × 8′ ½″ | 11.38 | PCS |
| 21 | Cripple Stud 2 × 4 × 16′ | 28.61 | PCS |
| 22 | Cripple Stud 2 × 6 × 16′ | 52.62 | PCS |
| 23 | Cripple Stud 2 × 8 × 16′ | 6.37 | PCS |
| 24 | Rough Sill 2 × 4 × 16′ | 7.10 | PCS |
| 25 | Rough Sill 2 × 6 × 16′ | 10.10 | PCS |
| 26 | Rough Sill 2 × 8 × 16′ | 1.75 | PCS |
| 27 | Stud 2 × 4 × 9′ #2 Douglas Fir | 77.45 | PCS |
| 28 | Stud 2 × 6 × 9′ #2 Douglas Fir | 37.52 | PCS |
| 29 | Stud 2 × 4 × 10′ #2 Douglas Fir | 487.78 | PCS |
| 30 | Stud 2 × 6 × 10′ #2 Douglas Fir | 206.98 | PCS |
| 31 | Stud 2 × 8 × 10′ #2 Douglas Fir | 18.63 | PCS |
| 32 | Stud 2 × 4 × 12′ #2 Douglas Fir | 26.10 | PCS |
| 33 | Stud 2 × 6 × 12′ #2 Douglas Fir | 14.62 | PCS |
| 34 | Stud 2 × 8 × 12′ #2 Douglas Fir | 5.67 | PCS |
| 35 | Stud 2 × 4 × 16′ #2 Douglas Fir | 1.36 | PCS |
| 36 | Stud 2 × 6 × 16′ #2 Douglas Fir | 19.86 | PCS |
| 37 | Top Plate 2 × 4 × 16′ #2 PT Douglas Fir | 117.40 | PCS |
| 38 | Top Plate 2 × 6 × 16′ #2 PT Douglas Fir | 73.28 | PCS |
| 39 | Top Plate 2 × 8 × 16′ #2 PT Douglas Fir | 8.02 | PCS |
| 40 | Exterior Wall Sheathing 7/16″ × 4′ × 8′ OSB | 199.99 | PCS |
| 41 | Sill Plate 2 × 4 × 16′ #2 PT Douglas Fir | 52.95 | PCS |
| 42 | Sill Plate 2 × 6 × 16′ #2 PT Douglas Fir | 28.30 | PCS |
| 43 | Sill Plate 2 × 8 × 16′ #2 PT Douglas Fir | 2.90 | PCS |
| 44 | Board 2 × 10 × 8′ | 14.00 | PCS |
| 45 | Board 1 ¾″ × 11 ⅞″ × 20′ LVL | 1.00 | PCS |
| 46 | Board 2 × 10 × 10′ | 19.99 | PCS |
| 47 | Board 2 × 6 × 10 | 35.00 | PCS |
| 48 | Board 2 × 8 × 10 | 5.00 | PCS |
| 49 | Board 2 × 10 × 16′ | 9.00 | PCS |
| 50 | Board 2 × 6 × 16 | 1.00 | PCS |
| 51 | Board 2 × 8 × 16 | 4.00 | PCS |
| 52 | Plywood 4 × 8′ ½″ | 220.04 | PCS |
| 53 | Rafter 2 × 6 × 16′ #2 Douglas Fir | 222.00 | PCS |
| 54 | Rafter 2 × 6 × 24′ #2 Douglas Fir | 40.00 | PCS |
| 55 | Roof Ridge Cap Shingles (25 LF per bundle) | 10.55 | PCS |
| 56 | Roof Ridge Vents (4 LF per bundle) | 65.96 | PCS |
| 57 | Roof Shingles (33.33-sq ft per Bundle) | 211.26 | PCS |
| 58 | Roof Starter Shingles (120 LF per bundle) | 3.27 | PCS |
| 59 | Roof Underlayment (100-sq ft per Bundle) | 7.04 | PCS |

As discussed, various machine learning models described herein may be trained to perform operations such as construction document page classification, roof element identification and/or wall element identification. FIG. 16 depicts an example of one suitable training approach.

FIG. 16 depicts an example of a process 1600 for training a machine learning model, in accordance with an aspect of the present disclosure. Training data 1612 may include one or more of inputs 1614 and known outcomes 1618 related to a machine learning model to be trained. The inputs 1614 may be from any applicable source including a component or set shown in the figures provided herein. Known outcomes 1618 may be included for machine learning models generated based on supervised or semi-supervised training. An unsupervised machine learning model might not be trained using known outcomes 1618. Known outcomes 1618 may include known or desired outputs for future inputs similar to or in the same category as inputs 1614 that do not have corresponding known outputs.

The training data 1612 may be provided to a training component 1630 that may apply the training data 1612 to generate a trained machine learning model 1650. According to an implementation, the training component 1630 may be provided comparison results 1616 that compare a previous output of the corresponding machine learning model to apply the previous result to re-train the machine learning model. The comparison results 1616 may be used by the training component 1630 to update the corresponding machine learning model. The training component 1630 may utilize machine learning networks and/or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, and/or discriminative models such as Decision Forests and maximum margin methods, or the like. The output of the process 1610 may be a trained machine learning model 1650.

A machine learning model disclosed herein may be trained by adjusting one or more weights, layers, and/or biases during a training phase. During the training phase, historical or simulated data may be provided as inputs to the model. The model may adjust one or more of its weights, layers, and/or biases based on such historical or simulated information. The adjusted weights, layers, and/or biases may be configured in a production version of the machine learning model (e.g., a trained model) based on the training. Once trained, the machine learning model may output machine learning model outputs in accordance with the subject matter disclosed herein. According to an implementation, one or more machine learning models disclosed herein may continuously update based on feedback associated with use or implementation of the machine learning model outputs.

FIG. 17 is a diagram illustrating an example of a computer system 1700, in accordance with an aspect of the present disclosure. Computer system 1700 is an example of any computing device used for an internal computer system, a remote computer system, a server, distributed system, data center, cloud-based system, or any component thereof.

Computer system 1700 may include one or more devices. For instance, computer system 1700 may include one or more of processor 1702, input/output device 1704, storage device 1708, memory 1710, communications interface 1716, and graphics processing unit (GPU) 1720. Each device may be connected via interface bus 1706, which is configured to communicate, transmit, and transfer data, controls, and commands among the various components of the computer system 1700.

Computer system 1700 includes at least one processor 1702 which is connected via bus 1706 to other system components. Examples of processor 1702 include, but are not limited to, a signal processor, micro controller, and a microprocessor. Computer system 1700 may also include one or more GPUs 1720. The GPUs 1720 may be used to perform operations associated with one or more machine learning models.

Input/output device 1704 may provide connections to user devices such as a keyboard, screen, microphone, speaker, other input/output devices, and computing components such as graphical processing units, serial ports, parallel ports, universal serial bus, and other input/output peripherals. Further, input/output device 1704 may be configured to facilitate communication between the computer system 1700 and other computing devices over a communications network and include, for example, a network interface controller, modem, wireless and wired interface cards, antenna, and other communication peripherals.

Storage device 1708 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, an optical disk, and so forth. Storage device 1708 may include a computer-readable medium.

A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as CD or DVD, flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements.

Memory 1710 may include Read Only Memory (ROM) 1712 and/or Random Access Memory (RAM) 1714. In some cases, computer system 1700 can include a cache of high-speed memory connected directly with, in close proximity to, or integrated as part of processor 1702 (not depicted).

Communications interface 1716, which can generally govern and manage the user input and system output. The communication interface may perform or facilitate receipt and/or transmission wired or wireless communications using wired and/or wireless transceivers, Examples of wireless communication include WiFi®, Cellular (e.g., 3G, LTE, 4G, 5G, etc.), Bluetooth® and so forth.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computer system from a general purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied-for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for case of explanation only and are not meant to be limiting.

While the present subject matter has been described in detail with respect to specific embodiments thereof, those skilled in the art, upon attaining an understanding of the foregoing, may readily produce alterations to, variations of, and equivalents to such embodiments. Accordingly, it should be understood that the present disclosure has been presented for purposes poses of example rather than limitation, and does not preclude the inclusion of such modifications, variations, and/or additions to the present subject matter as would be readily apparent to one of ordinary skill in the art.

Aspect 1. A method comprising: accessing a construction document associated with a construction project, the construction document comprising pages; providing the pages to a first machine learning model to generate classified pages, wherein each classified page identifies a page type and a region; providing the classified pages to a second machine learning model to generate segmented pages comprising one or more objects, each object corresponding to a building element; analyzing the one or more objects to determine coordinates and properties; and determining, from the coordinates and the properties, a bill of materials associated with the construction project.

Aspect 2. The method of aspect 1, further comprising: presenting one or more of the classified pages on a display of a user device; receiving input from the user device, wherein the input is associated with a region of a first classified page of the classified pages; and adjusting the region of the first classified page based on inputs received from a user device.

Aspect 3. The method of aspect 1, further comprising: presenting one of the segmented pages on a display of a user device; and adjusting one or more objects of the one of the segmented pages based on inputs received from the user device.

Aspect 4. The method of aspect 1, wherein the second machine learning model generates a segmentation mask that identifies a presence of a roof on a first classified page of the classified pages, the method further comprising: calculating, from the segmentation mask, an area of the roof; applying the segmentation mask to the first classified page to create a masked image; analyzing the masked image to identify distinct shapes and edges of the distinct shapes; identifying, from the distinct edges, structural lines; determining, from the structural lines, one or more slopes associated with the roof; and associating the one or more slopes with the building elements.

Aspect 5. The method of aspect 1, wherein the second machine learning model is trained to identify one or more wall segments, the method further comprising: receiving from the second machine learning model, a first mask representing first locations of interior walls and a second mask representing second locations of exterior walls; calculating first dimensions of the interior walls from the first mask and second dimensions of the exterior walls from the second mask; and associating first dimensions of the interior walls and second dimensions of the exterior walls with one or more of the building elements.

Aspect 6. The method of aspect 1, further comprising: visualizing the one or more objects of the segmented pages on a display device.

Aspect 7. The method of aspect 1, wherein the first machine learning model comprises one or more of a convolutional neural network (CNNs), a transformer-based vision model, and a region-based CNN (R-CNN).

Aspect 8. The method of aspect 1, wherein the page type is one or more of electrical, structural, elevation, flat roof, sloped roof, mechanical, and plumbing.

Aspect 9. The method of aspect 1, further comprising adjusting one or more of a size and a shape of one or more of the pages prior to providing the pages to the first machine learning model.

Aspect 10. The method of aspect 1, wherein the second machine learning model is trained to identify one or more of an interior wall and an exterior wall.

Aspect 11. The method of aspect 1, wherein the second machine learning model is trained to identify, for each of the one or more objects, an associated roof slope and area.

Aspect 12. An apparatus comprising: A memory; and a processor coupled to the memory and configured to perform operations comprising: accessing a construction document associated with a construction project, the construction document comprising pages; providing the pages to a first machine learning model to generate classified pages, wherein each classified page identifies a page type and a region; providing the classified pages to a second machine learning model to generate segmented pages comprising one or more objects, each object corresponding to a building element; analyzing the one or more objects to determine coordinates and properties; and determining, from the coordinates and the properties, a bill of materials associated with the construction project.

Aspect 13. The apparatus of aspect 12, wherein the processor is further configured to perform operations comprising: presenting one or more of the classified pages on a display of a user device; receiving input from the user device, wherein the input is associated with a region of a first classified page of the classified pages; and adjusting the region of the first classified page based on inputs received from a user device.

Aspect 14. The apparatus of aspect 12, wherein the second machine learning model generates a segmentation mask that identifies a presence of a roof on a first classified page of the classified pages, wherein the processor is further configured to perform operations comprising: calculating, from the segmentation mask, an area of the roof; applying the segmentation mask to the first classified page to create a masked image; analyzing the masked image to identify distinct shapes and edges of the distinct shapes; identifying, from the distinct edges, structural lines; determining, from the structural lines, one or more slopes associated with the roof; and associating the one or more slopes with the building elements.

Aspect 15. The apparatus of aspect 12, wherein the second machine learning model is trained to identify one or more wall segments, wherein the processor is further configured to perform operations comprising: receiving from the second machine learning model, a first mask representing first locations of interior walls and a second mask representing second locations of exterior walls; calculating first dimensions of the interior walls from the first mask and second dimensions of the exterior walls from the second mask; and associating first dimensions of the interior walls and second dimensions of the exterior walls with one or more of the building elements.

Aspect 16. A non-transitory computer readable medium comprising instructions, that when executed by a processor, cause the processor to perform operations comprising: accessing a construction document associated with a construction project, the construction document comprising pages; providing the pages to a first machine learning model to generate classified pages, wherein each classified page identifies a page type and a region; providing the classified pages to a second machine learning model to generate segmented pages comprising one or more objects, each object corresponding to a building element; analyzing the one or more objects to determine coordinates and properties; and determining, from the coordinates and the properties, a bill of materials associated with the construction project.

Aspect 17. The non-transitory computer readable medium of aspect 16, further comprising: presenting one or more of the classified pages on a display of a user device; receiving input from the user device, wherein the input is associated with a region of a first classified page of the classified pages; and adjusting the region of the first classified page based on inputs received from a user device.

Aspect 18. The non-transitory computer readable medium of aspect 16, wherein the second machine learning model generates a segmentation mask that identifies a presence of a roof on a first classified page of the classified pages, wherein when executed by the processor, the instructions cause the processor to perform operations comprising: calculating, from the segmentation mask, an area of the roof; applying the segmentation mask to the first classified page to create a masked image; analyzing the masked image to identify distinct shapes and edges of the distinct shapes; identifying, from the distinct edges, structural lines; determining, from the structural lines, one or more slopes associated with the roof; and associating the one or more slopes with the building elements.

Aspect 19. The non-transitory computer readable medium of aspect 16, wherein the second machine learning model is trained to identify one or more wall segments, wherein when executed by the processor, the instructions cause the processor to perform operations comprising: receiving from the second machine learning model, a first mask representing first locations of interior walls and a second mask representing second locations of exterior walls; calculating first dimensions of the interior walls from the first mask and second dimensions of the exterior walls from the second mask; and associating first dimensions of the interior walls and second dimensions of the exterior walls with one or more of the building elements.

Aspect 20. The non-transitory computer readable medium of aspect 16, wherein the first machine learning model comprises one or more of a convolutional neural network (CNNs), a transformer-based vision model, and a region-based CNN (R-CNN).

Aspect 21. A method for identifying roof elements represented in a construction document, the method comprising: providing a first page associated with a roof to a semantic segmentation model to generate a segmentation mask; calculating, from the segmentation mask, an area of the roof; applying the segmentation mask to the first page to create a masked image; analyzing the masked image to identify one or more distinct shapes; identifying one or more edges of the distinct shapes; extracting, from the edges, a simplified line representation; identifying one or more structural lines from the simplified line representation; determining, from the structural lines, one or more slopes associated with the roof; comparing the slopes against lines represented in an additional page of the construction document to create a subset of the slopes, wherein the additional page comprises one or more structural diagrams; and outputting the area and the subset of the slopes.

Aspect 22. A method for identifying wall elements represented in a construction document, the method comprising: providing a page of a construction document to a convolutional machine learning model, wherein the convolutional machine learning model is trained to identify one or more wall segments; receiving from the convolutional machine learning model, a first mask representing first locations of interior walls and a second mask representing second locations of exterior walls; calculate first dimensions of the interior walls from the first mask and second dimensions of the exterior walls from the second mask; and output first dimensions of the interior walls and second dimensions of the exterior walls.

Aspect 23. The method of aspect 22, wherein the convolutional machine learning model assigns a classification score to each segment, wherein the score indicates a confidence of whether the segment represents an interior wall or an exterior wall.

Aspect 24. The method of aspect 22, further comprising: normalizing the page to a predetermined size prior to providing the page to the convolutional machine learning model.

What is claimed is:

1. A method comprising:
accessing a construction document associated with a construction project, the construction document comprising pages;
providing the pages to a first machine learning model to generate classified pages, wherein each classified page identifies a page type and a region;
providing the classified pages to a second machine learning model to generate segmented pages comprising one or more objects, each object corresponding to a building element;
analyzing the one or more objects to determine coordinates and properties; and
determining, from the coordinates and the properties, a bill of materials associated with the construction project.

2. The method of claim 1, further comprising:
presenting one or more of the classified pages on a display of a user device;
receiving input from the user device, wherein the input is associated with a region of a first classified page of the classified pages; and
adjusting the region of the first classified page based on inputs received from a user device.

3. The method of claim 1, further comprising:
presenting one of the segmented pages on a display of a user device; and
adjusting one or more objects of the one of the segmented pages based on inputs received from the user device.

4. The method of claim 1, wherein the second machine learning model generates a segmentation mask that identifies a presence of a roof on a first classified page of the classified pages, the method further comprising:
calculating, from the segmentation mask, an area of the roof;
applying the segmentation mask to the first classified page to create a masked image;
analyzing the masked image to identify distinct shapes and edges of the distinct shapes;
identifying, from the distinct edges, structural lines;
determining, from the structural lines, one or more slopes associated with the roof; and
associating the one or more slopes with the building elements.

5. The method of claim 1, wherein the second machine learning model is trained to identify one or more wall segments, the method further comprising:
receiving from the second machine learning model, a first mask representing first locations of interior walls and a second mask representing second locations of exterior walls;
calculating first dimensions of the interior walls from the first mask and second dimensions of the exterior walls from the second mask; and
associating first dimensions of the interior walls and second dimensions of the exterior walls with one or more of the building elements.

6. The method of claim 1, further comprising:
visualizing the one or more objects of the segmented pages on a display device.

7. The method of claim 1, wherein the first machine learning model comprises one or more of a convolutional neural network (CNNs), a transformer-based vision model, and a region-based CNN (R-CNN).

8. The method of claim 1, wherein the page type is one or more of electrical, structural, elevation, flat roof, sloped roof, mechanical, and plumbing.

9. The method of claim 1, further comprising adjusting one or more of a size and a shape of one or more of the pages prior to providing the pages to the first machine learning model.

10. The method of claim 1, wherein the second machine learning model is trained to identify one or more of an interior wall and an exterior wall.

11. The method of claim 1, wherein the second machine learning model is trained to identify, for each of the one or more objects, an associated roof slope and area.

12. An apparatus comprising:
A memory; and
a processor coupled to the memory and configured to perform operations comprising:
accessing a construction document associated with a construction project, the construction document comprising pages;
providing the pages to a first machine learning model to generate classified pages, wherein each classified page identifies a page type and a region;
providing the classified pages to a second machine learning model to generate segmented pages comprising one or more objects, each object corresponding to a building element;
analyzing the one or more objects to determine coordinates and properties; and
determining, from the coordinates and the properties, a bill of materials associated with the construction project.

13. The apparatus of claim 12, wherein the processor is further configured to perform operations comprising:
presenting one or more of the classified pages on a display of a user device;
receiving input from the user device, wherein the input is associated with a region of a first classified page of the classified pages; and
adjusting the region of the first classified page based on inputs received from a user device.

14. The apparatus of claim 12, wherein the second machine learning model generates a segmentation mask that identifies a presence of a roof on a first classified page of the classified pages, wherein the processor is further configured to perform operations comprising:
calculating, from the segmentation mask, an area of the roof;
applying the segmentation mask to the first classified page to create a masked image;
analyzing the masked image to identify distinct shapes and edges of the distinct shapes;
identifying, from the distinct edges, structural lines;
determining, from the structural lines, one or more slopes associated with the roof; and
associating the one or more slopes with the building elements.

15. The apparatus of claim 12, wherein the second machine learning model is trained to identify one or more wall segments, wherein the processor is further configured to perform operations comprising:
receiving from the second machine learning model, a first mask representing first locations of interior walls and a second mask representing second locations of exterior walls;
calculating first dimensions of the interior walls from the first mask and second dimensions of the exterior walls from the second mask; and
associating first dimensions of the interior walls and second dimensions of the exterior walls with one or more of the building elements.

16. A non-transitory computer readable medium comprising instructions, that when executed by a processor, cause the processor to perform operations comprising:
accessing a construction document associated with a construction project, the construction document comprising pages;
providing the pages to a first machine learning model to generate classified pages, wherein each classified page identifies a page type and a region;
providing the classified pages to a second machine learning model to generate segmented pages comprising one or more objects, each object corresponding to a building element;
analyzing the one or more objects to determine coordinates and properties; and
determining, from the coordinates and the properties, a bill of materials associated with the construction project.

17. The non-transitory computer readable medium of claim 16, further comprising:
presenting one or more of the classified pages on a display of a user device;
receiving input from the user device, wherein the input is associated with a region of a first classified page of the classified pages; and
adjusting the region of the first classified page based on inputs received from a user device.

18. The non-transitory computer readable medium of claim 16, wherein the second machine learning model generates a segmentation mask that identifies a presence of a roof on a first classified page of the classified pages, wherein when executed by the processor, the instructions cause the processor to perform operations comprising:
calculating, from the segmentation mask, an area of the roof;
applying the segmentation mask to the first classified page to create a masked image;
analyzing the masked image to identify distinct shapes and edges of the distinct shapes;
identifying, from the distinct edges, structural lines;
determining, from the structural lines, one or more slopes associated with the roof; and
associating the one or more slopes with the building elements.

19. The non-transitory computer readable medium of claim 16, wherein the second machine learning model is trained to identify one or more wall segments, wherein when executed by the processor, the instructions cause the processor to perform operations comprising:
receiving from the second machine learning model, a first mask representing first locations of interior walls and a second mask representing second locations of exterior walls;
calculating first dimensions of the interior walls from the first mask and second dimensions of the exterior walls from the second mask; and
associating first dimensions of the interior walls and second dimensions of the exterior walls with one or more of the building elements.

20. The non-transitory computer readable medium of claim 16, wherein the first machine learning model comprises one or more of a convolutional neural network (CNNs), a transformer-based vision model, and a region-based CNN (R-CNN).
